(19) United States
(12) Patent Application Publication
(10) Pub. No.: US 2018/0074405 A1
(43) Pub. Date: Mar. 15, 2018

(54) TRANSFER-TYPE PHOTOSENSITIVE REFRACTIVE INDEX ADJUSTMENT FILM, METHOD FOR FORMING REFRACTIVE INDEX ADJUSTMENT PATTERN, AND ELECTRONIC COMPONENT

(71) Applicant: Hitachi Chemical Company, LTD., Tokyo (JP)

(72) Inventors: Mayumi SATO, Tokyo (JP); Tadahiro KIMURA, Tokyo (JP); Hideki YOSHIDA, Tokyo (JP); Koji ABE, Tokyo (JP); Takumi WATANABE, Tokyo (JP)

(21) Appl. No.: 15/552,020

(22) PCT Filed: Feb. 20, 2015
(86) PCT No.: PCT/JP2015/000824

§ 371 Date: Nov. 29, 2017

(51) Int. Cl. G03F 7/033; G03F 7/031; G03F 7/20; G03F 7/32; G03F 7/38; G03F 7/11; G06F 3/044

(52) U.S. Cl. CPC G03F 7/033; G03F 7/031; G03F 7/2002; G06F 2203/04103; G03F 7/38; G03F 7/11; G06F 3/044; G03F 7/322

(57) ABSTRACT

A transfer-type photosensitive refractive index adjustment film comprising a supporting film, a photosensitive resin layer and a high refractive index layer provided on the photosensitive resin layer, wherein the photosensitive resin layer and the high refractive index layer are composed mainly of an organic substance.

### TECHNICAL FIELD

The present invention relates to a transfer-type photosensitive refractive index-adjusting film, a method for forming a refractive index-adjusting film and an electronic component. In particular, the present invention relates to a transfer-type photosensitive refractive index-adjusting film that can form easily a cured film having both functions; i.e. a function as a protective film of a transparent electrode, and a function of allowing a transparent electrode pattern to be invisible or improving visibility of a touch screen.

### BACKGROUND ART

In a display, etc. of a large-sized electronic device such as PCs and TVs; a small-sized electronic device such as a car navigation, a portable phone and an electronic dictionary, an OA or FA device, a liquid crystal display device or a touch panel (touch sensor) is used. In these liquid crystal display devices or touch panels, an electrode made of a transparent electrode material is provided. As the transparent electrode material, ITO (Indium-Tin-Oxide), indium oxide or tin oxide constitutes the mainstream thereof since they exhibit high transmittance for visible rays.

As the touch panel, various types of touch panel have already been put into practical use. Since it enables finger tips to conduct multiple detection, a projected capacitive touch panel has excellent operability that it can issue complicated instructions. Due to such excellent operability, in a device having a small-sized display such as a portable phone or a portable music player, a projected capacitive touch panel has been actively used as an input device on a display screen.

In general, in a projected capacitive touch panel, in order to express two-dimensional coordinates of the X-axis and the Y-axis, plural X electrodes and plural Y electrodes that cross orthogonally the X electrodes form a two-layer structure pattern. As these electrodes, in recent years, use of conductive fibers, the representative examples of which include Ag nanowires and carbon nanotubes, has been examined. However, ITO still constitutes the mainstream of the electrode material.

Meanwhile, since a perimeter area of a touch panel is a region where no touch position can be detected, it is important to reduce the area of such perimeter area in order to improve the product value. In order to transmit detected signals of touch positions, metal wiring is required to be provided in the perimeter area. For narrowing the perimeter area, it is required to decrease the width of the metal wiring. In respect of conductivity, the metal wiring is generally made of copper.

When contacting the finger tips, corrosive components such as water and salt may enter the inside into a touch panel from a sensing area. If corrosive components enter the inside of a touch panel, the above-mentioned metal wiring corrodes, and as a result, an electrical resistance between an electrode and a driving circuit may be increased or disconnection may occur.

A projected capacitive touch panel in which an insulating layer is formed on a metal in order to prevent corrosion of metal wiring is disclosed (Patent Document 1, for example). In this touch panel, a silicon dioxide layer is formed on a metal by plasma chemical deposition method (plasma CVD method), thereby preventing corrosion of a metal. However, this method requires a high-temperature treatment, and there are problems that usable substrates are restricted or production costs are increased, or the like.

Under such circumstances, the inventors of the present invention have proposed a method in which a photosensitive resin layer made of a specific photosensitive resin composition is provided on a transparent substrate, and the metal wiring on the transparent substrate is protected by subjecting this photosensitive resin layer to light exposure and development (Patent Document 2, for example).

As mentioned above, in a projected capacitive touch panel, on a substrate, plural X electrodes and plural Y electrodes that cross orthogonally to the X electrodes made of transparent electrode materials are formed, thereby to form a transparent electrode pattern having a two-layer structure. A difference in color becomes large due to optical reflection of a part in which a transparent electrode pattern is formed and a part in which a transparent electrode pattern is not formed. As a result, when it is formed into a module, the so-called “patter invisibility phenomenon” in which a transparent electrode pattern is pictured in a screen may occur. Further, between a substrate and a transparent electrode or between a visibility improvement film (OCA: Optical Clear Adhesive) that adheres a cover glass used for forming the film into a module and a transparent electrode pattern, the intensity of reflected light is increased to lower the transmission ratio of a screen.

In order to prevent occurrence of “pattern visibility phenomenon” or lowering in transmittance, disclosed is a transparent conductive film in which an IM layer (optical adjusting layer, also referred to as an index matching layer) is provided between a substrate and a transparent electrode pattern, thereby to suppress difference in color, and as a result, pattern visibility phenomenon and lowering in transmittance of a screen (Patent Document 3, for example) are prevented.

However, in the technology of Patent Document 3, effects of suppressing pattern visibility phenomenon and lowering in transmittance are not sufficient. Further, in the above-mentioned technology, there is a problem that, it is required to conduct coating by sputtering, spin coating, etc. in order to provide an IM layer, and in addition to this step, suppression of corrosion or metal wiring in a perimeter region of a touch panel is required to be conducted separately, resulting in an increase in number of steps.

Further, in order to combine the technology of Patent Document 3 with the technology of Patent Document 2 regardless of an increase in production steps, even if an attempt is made to form an IM layer on a transparent electrode pattern after forming an IM layer on a substrate and forming a transparent electrode pattern on the IM layer, since irregularities are present in the surface on which the transparent electrode pattern, the IM layer cannot be formed uniformly.

As a method for preventing the transparent electrode pattern from being visibly recognized, a transfer film having a low refractive first curable transparent resin layer and a high refractive second curable transparent resin layer, which are adjusted to have a specific refractive index, is disclosed (see Patent Document 4).

### RELATED ART DOCUMENTS

### Patent Documents

Patent Document 1: JP-A-2011-28594
Patent Document 2: WO2013/084873
Patent Document 3: JP-A-H08-240800
Patent Document 4: WO2014/084112

### SUMMARY OF THE INVENTION

However, according to the method of Patent Document 4, there is room for improvement in terms of forming a cured film that can satisfy both reduction in transmittance of a screen and protection of a sensor metal wiring, which is insufficient in developability when a predetermined cured film is formed. As specific configuration of the transfer film, a six-layer film composed of a temporary support/thermoplastic resin layer/intermediate layer/first curable transparent resin layer/second curable transparent resin layer/protective film is disclosed. In respect of productivity of a multilayer film, there is room for improvement.

Further, in the technology of Patent Document 4, a high refractive index is attained by mixing a dispersion of zirconium oxide as metal oxide ultrafine particles with a binder resin, followed by coating, the ultrafine particle-dispersed system has room for improvement in respect of forming a uniform film or adaptability to the environment.

An object of the present invention is to provide a transfer-type photosensitive refractive index-adjusting film capable of forming a cured form easily that can attain both prevention of “pattern visibility phenomenon” of a transparent electrode, lowering in transmittance of a screen and protection of a sensor metal wiring.

The inventors of the invention made intensive studies in order to solve the above-mentioned problem. As a result, the inventors have found that, a thin IM layer can be formed on a transparent conductive pattern by using a transfer-type photosensitive refractive index-adjusting film composed of a photosensitive resin layer and a high refractive index layer, suppression of an increase in difference in color, prevention of the “pattern visibility phenomenon” and improvement of visibility of a touch screen by elimination of lowering in transmittance of a screen and prevention of corrosion of the metal wiring can be attained simultaneously In addition, by forming the photosensitive resin layer and the high refractive index layer mainly of an organic substance, developability can be improved. The invention has been made based on these findings.

The specific embodiments of the invention are described below.

1. A transfer-type photosensitive refractive index adjustment film comprising a supporting film, a photosensitive resin layer provided on the supporting film and a high refractive index layer provided on the photosensitive resin layer,

wherein the photosensitive resin layer and the high refractive index layer are composed mainly of an organic substance.

2. The transfer-type photosensitive refractive index adjustment film according to 1, wherein the photosensitive resin layer and the high refractive index layer consist essentially of an organic substance.
3. The transfer-type photosensitive refractive index adjustment film according to 1, wherein the photosensitive resin layer and the high refractive index layer essentially do not comprise a metal oxide.
4. The transfer-type photosensitive refractive index adjustment film according to any one of 1 to 3, wherein the high refractive index layer comprises a compound having a triazine ring or a compound having an isocyanuric acid skeleton.
5. The transfer-type photosensitive refractive index adjustment film according to any one of 1 to 4, wherein the high refractive index layer comprises a compound having a fluorene skeleton.
6. The transfer-type photosensitive refractive index adjustment film according to any one of 1 to 4, wherein the high refractive index layer comprises a compound having a biphenyl skeleton.
7. The transfer-type photosensitive refractive index adjustment film according to any one of 1 to 4, wherein the high refractive index layer comprises a compound having a naphthalene skeleton.
8. The transfer-type photosensitive refractive index adjustment film according to any one of 1 to 7, wherein the high refractive index layer has a refractive index of 1.50 to 1.90 at a wavelength of 633 nm.
9. The transfer-type photosensitive refractive index adjustment film according to any one of 1 to 8, wherein the high refractive index layer has a film thickness of 50 to 1000 nm.
10. The transfer-type photosensitive refractive index adjustment film according to any one of 1 to 9, wherein the photosensitive resin layer comprises a binder polymer, a photopolymerizable compound and a photopolymerization initiator.
11. The transfer-type photosensitive refractive index adjustment film according to 10, wherein the photopolymerization initiator comprises an oxime ester compound.
12. The transfer-type photosensitive refractive index adjustment film according to 10 or 11, wherein the binder polymer has a carboxyl group.
13. The transfer-type photosensitive refractive index adjustment film according to any one of 10 to 12, wherein the binder polymer has a structural unit derived from at least one compound selected from the group consisting of (meth)acrylic acid, (meth)acrylic acid glycidyl ester, (meth)acrylic acid benzyl ester, styrene, (meth)acrylic acid methyl ester, (meth)acrylic acid ethyl ester, (meth)acrylic acid butyl ester and (meta)acrylic acid 2-ethylhexyl ester.
14. The transfer-type photosensitive refractive index adjustment film according to any one of 10 to 13, wherein the photosensitive resin layer comprises a phosphoric acid ester compound.
15. The transfer-type photosensitive refractive index adjustment film according to any one of 1 to 14, wherein the minimum value of the visible ray transmittance of the photosensitive resin layer and the high refractive index layer at a wavelength of 400 to 700 nm is 90.00% or more.
16. The transfer-type photosensitive refractive index adjustment film according to any one of 1 to 15, wherein the total thickness of the photosensitive resin layer and the high refractive index layer is 30 μm or less.
17. A method for forming a refractive index adjustment pattern that comprises:

a step of laminating the high refractive index layer and the photosensitive resin layer by using the transfer-type photosensitive refractive index adjustment film according to any one of 1 to 16 such that the high refractive index layer is in close contact with a substrate; and

a step of forming a refractive index adjustment pattern in which, after exposing prescribed parts of the high refractive index layer and the photosensitive resin layer on the substrate, parts other than said prescribed parts are removed, thereby to form a refractive index adjustment pattern.

18. An electronic component comprising a refractive index adjustment pattern obtained by the forming method according to 17.

According to the invention, it is possible to provide a transfer-type photosensitive refractive index-adjusting film capable of forming a cured film easily that has both a function as a protective film of a transparent electrode and a function of allowing a transparent electrode pattern to be invisible or improving visibility of a touch screen. Further, the transfer-type photosensitive refractive index-adjusting film of the invention is excellent in developability at the time of forming a refractive index-adjusting pattern.

### BRIEF DESCRIPTION OF THE DRAWINGS

FIG. 1 is a schematic cross sectional view showing the transfer-type photosensitive refractive index-adjusting film of the invention:

FIG. 2 is a schematic cross sectional view showing one embodiment in which the transfer-type photosensitive refractive index-adjusting film of the invention is used in a substrate with a transparent conductive pattern; and

FIG. 3 is a schematic plan view showing an electronic component according to one embodiment of the invention.

### MODE FOR CARRYING OUT THE INVENTION

Hereinbelow, the mode for carrying out the present invention will be explained in detail. However, the present invention is not limited to the embodiments mentioned below.

In the specification, the “(meth)acrylic acid” means an acrylic acid or a methacrylic acid, and the “(meth)acrylate” means acrylate or methacrylate corresponding thereto. The “(poly)oxyethylene chain” means an oxyethylene group or a polyoxyethylene group. The “(poly)oxypropylene chain” means an oxypropylene group or a polyoxypropylene group. The “A or B” means inclusion of either one of A and B or inclusion of both A and B.

In the specification, the “step” includes not only an independent step. That is, if a step cannot be clearly distinguished from other steps, the step is included in the “step” as long as the step attains its prescribed effects. The numerical range indicated by using “to” means a range including numerical values indicated before and after the “to” as a minimum value and a maximum value, respectively.

Further, as for the content of each component in the composition in the specification, when plural substances corresponding to these components are present in the composition, unless otherwise indicated, the content means the total amount of these plural substances in the composition. In addition, unless otherwise indicated, exemplified materials may be used singly or in combination of two or more.

### (Transfer-Type Photosensitive Refractive Index-Adjusting Film)

The transfer-type photosensitive refractive index-adjusting film comprises a supporting film, a photosensitive resin layer provided on the supporting film and a high refractive index layer provided on the photosensitive resin layer, and is characterized in the photosensitive resin layer and in that the photosensitive resin layer are composed mainly of an organic substance.

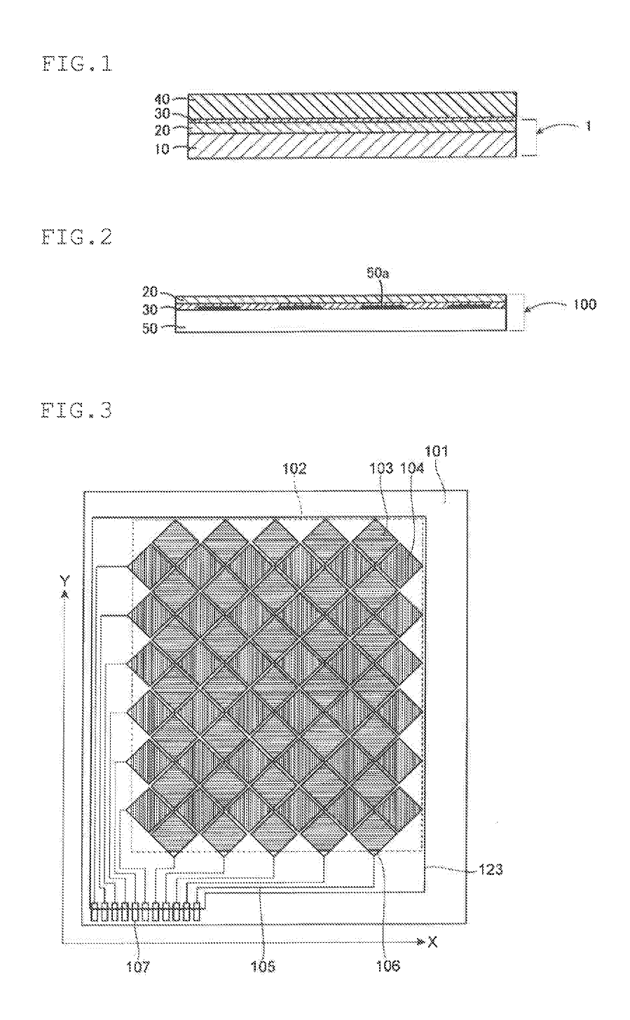

FIG. 1 is a schematic cross sectional view showing one embodiment of the transfer-type photosensitive refractive index-adjusting film according to the invention. A transfer-type photosensitive refractive index film 1 shown in FIG. 1 is provided with a supporting film 10, a photosensitive resin layer 20 provided on the supporting film, and a high refractive index layer 30 provided on the photosensitive resin layer. As shown in FIG. 1, the transfer-type photosensitive refractive index adjustment film may comprise a protective film 40 provided on the side opposite to the photosensitive resin layer 20 of the high refractive index layer 30.

In the specification, the boundary between the high refractive index layer and the photosensitive resin layer is not necessarily clear, and it may be in a state in which the photosensitive resin layer is mixed with the high refractive index layer.

By using the above-mentioned transfer-type photosensitive refractive index-adjusting film, a cured film that satisfies, for example, a function of protecting the metal wiring in the perimeter of a touch panel or a transparent electrode and a function of allowing a transparent electrode pattern to be invisible or improving visibility of a touch screen can be formed simultaneously.

FIG. 2 is a schematic cross-sectional view showing one embodiment in which the transfer-type photosensitive refractive-index adjustment film of the invention is used in a substrate provided with a transparent electrode pattern. In FIG. 2, a high refractive index layer 30 is provided on a substrate 50 with a transparent electrode pattern 50a such as ITO such that it covers the pattern 50a. A photosensitive resin layer 20 is provided thereon, whereby a laminate 100 is configured.

Hereinbelow, an explanation is made on the supporting film, the photosensitive resin layer, the high refractive index layer and the protective film.

### (Supporting Film)

As the supporting film 10, a polymer film can be used. As the polymer film, polyethylene terephthalate, polycarbonate, polyethylene, polypropylene, polyethersulfone, cycloolefin polymer or the like can be given.

As for the thickness of the supporting film 10, in respect of securing coating property and suppressing lowering in resolution when irradiating active rays through the supporting film 10, the thickness is preferably 5 to 100 μm, more preferably 10 to 70 μm, further preferably 15 to 40 μm, and particularly preferably 15 to 35 μm.

### (Photosensitive Resin Layer)

In the invention, the photosensitive resin layer 20 is formed mainly of an organic substance. By this, developability is improved. In the present invention, the “photosensitive resin layer is formed mainly of an organic substance” means that the content of an organic substance relative to the entire raw material is 90 mass % or more (preferably 95 mass % or more, more preferably 99 mass % or more). It is further preferred that the photosensitive resin layer 20 consist essentially of an organic substance. The “consist essentially of an organic substance” means that the content of an inorganic substance relative to the entire raw material forming the photosensitive resin layer is less than 0.1 mass %. Particularly preferably, the photosensitive resin layer 20 essentially do not comprise a metal oxide. The “essentially do not comprise a metal oxide” specifically means that the content of a metal oxide relative to the entire raw material forming the photosensitive resin layer is less than 0.01 mass %.

The organic substance means a compound excluding those classified into an inorganic substance (e.g. carbonates of metal elements such as calcium carbonate and sodium hydrogencarbonate, oxides such as carbon monoxide, carbon dioxide, cyanides and the like) from a group of compounds containing carbon C. For example, organosiloxane is an organic substance and a metal oxide is an inorganic substance.

It is preferred that the photosensitive resin layer 20 be formed of a binder polymer (hereinafter, often referred to as the component (A)), a photopolymerizable compound (hereinafter, often referred to as the component (B)) and a photopolymerization initiator (hereinafter referred to as the component (C)).

As the component (A), in respect of possibility of patterning by alkali development, it is preferable to use a binder polymer having a carboxyl group.

As the component (A), a copolymer comprising structural units derived from (meth)acrylic acid and (meth)acrylic acid alkyl ester is preferable. The copolymer mentioned above may contain, as its structural unit, other monomers that can copolymerize with the (meth)acrylic acid and the (meth)acrylic acid alkyl ester. Specifically, (meth)acrylic acid glycidyl ester, (meth)acrylic acid benzyl ester, styrene or the like can be given.

As the above-mentioned (meth)acrylic acid alkyl ester, (meth)acrylic acid methyl ester, (meth)acrylic ethyl ester, (meth)acrylic acid butyl ester, (meth)acrylic acid 2-ethylhexyl ester, (meth)acrylic hydroxyl ethyl ester or the like can be given.

Among these, in respect of alkaline developability (for an inorganic aqueous alkaline solution), patterning property and transparency, a binder polymer containing a structural unit derived from a compound selected from (meth)acrylic acid glycidyl ester, (meth)acrylic acid benzyl ester, styrene, (meth)acrylic acid methyl ester, (meth)acrylic acid ethyl ester and (meth)acrylic acid 2-ethylhexyl ester is preferable.

In respect of resolution, the weight-average molecular weight of the component (A) is preferably 10,000 to 200,000, more preferably 15,000 to 150,000, further preferably 30,000 to 150,000, particularly preferably 30,000 to 100,000, with 40,000 to 100,000 being significantly preferable. Meanwhile, the weight-average molecular weight can be measured by a gel permeation method with reference to the Examples of the present specification.

The acid value of the component (A) is preferably 75 mgKOH/g or more in respect of forming a protective film having a desired shape easily by alkali development. Further, in respect of attaining both easiness in control of the shape of a protective film and rust prevention of a protective film, the acid value is preferably 75 to 200 mgKOH/g, more preferably 75 to 150 mgKOH/g, further preferably 75 to 120 mgKOH/g, with 78 to 120 mgKOH/g being particularly preferable. The acid value can be measured with reference to the Examples of the present specification.

In respect of further improving rust prevention properties, the hydroxyl value of the component (A) is preferably 50 mgKOH/g or less, more preferably 45 mgKOH/g or less. The hydroxyl value can be measured with reference to the Examples of the present specification.

As the component (B), a photopolymerizable compound having an ethylenically unsaturated group can be used. As the photopolymerizable compound having an ethylenically unsaturated group, a monofunctional vinyl monomer, a bifunctional vinyl monomer, or a polyfunctional vinyl monomer having at least three polymerizable ethylenically unsaturated groups can be given.

As the monofunctional vinyl monomer, those exemplified above as the monomer used for the synthesis of a copolymer that is a preferable example of the component (A) can be given.

As the bifunctional vinyl monomer, polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, bisphenol A diglycidyl ether di(meth)acrylate or the like can be given.

As the polyfunctional vinyl monomer having at least three ethylenically polymerizable unsaturated groups, those conventionally known in the art can be used without particular restrictions. In respect of prevention of corrosion of the metal wiring or the transparent electrode and in respect of developability, it is preferable to use a (meth)acrylate compound having a skeleton derived from trimethylol propane such as trimethylol propane tri(meth)acrylate; a (meth)acrylate compound having a skeleton derived from tetramethylol methane such as tetramethylol methane tri(meth)acrylate and tetramethylol methane tetra(meth)acrylate; a (meth)acrylate compound having a skeleton derived from pentaerythritol such as pentaerythritol tri(meth)acrylate and pentaerythritol tetra(meth)acrylate; a meth(acrylate) compound having a skeleton derived from dipentaerythritol such as dipentaerythritol penta(meth)acrylate and dipentaerythritol hexa(meth)acrylate; a (meth)acrylate compound having a skeleton derived from ditrimethylol propane such as ditrimethylol propane tetra(meth)acrylate; or a (meth)acrylate compound having a skeleton derived from diglycerin.

More specifically, it is preferable to include a (meth)acrylate compound having a skeleton derived from pentaerythritol, a (meth)acrylate compound having a skeleton derived from dipentaerythritol, a (meth)acrylate compound having a skeleton derived from trimethylolpropane or a (meth)acrylate compound having a skeleton derived from ditrimethylolpropane. It is more preferable to include a (meth)acrylate compound having a skeleton derived from dipentaerythritol or a (meth)acrylate compound having a skeleton derived from ditrimethylolpropane. It is further preferable to include a (meth)acrylate compound having a skeleton derived from ditrimethylolpropane.

As for the “(meth)acrylate compound having a skeleton derived from . . . ”, an explanation will be made taking as an example a (meth)acrylate compound having a skeleton derived from ditrimethylolpropane. The (meth)acrylate having a skeleton derived from ditrimethylolpropane means an esterified product of ditrimethylolpropane and (meth)acrylic acid. The esterified product includes compounds obtained by esterifying an alkylene oxy group. It is preferred that the maximum number of ester bonds in a single molecule of the esterified product mentioned above be 4. Compounds having 1 to 3 ester bonds may be mixed in.

When a monomer having at least three polymerizable ethylenically unsaturated groups in a single molecule is used in combination with a monofunctional vinyl monomer or a bifunctional vinyl monomer, although no specific restrictions are imposed on the amount ratio, in respect of improving photocurability and prevention of electrode corrosion, the amount ratio of a monomer having at least three polymerizable ethylenically unsaturated groups in a molecule is preferably 30 to 100 parts by mass, more preferably 50 to 100 parts by mass and further preferably 75 to 100 parts by mass, relative to 100 parts by mass of the total amount of the photopolymerizable compounds contained in the photosensitive resin composition.

As for the contents of the component (A) and the component (B), the content of the component (A) is preferably 35 to 85 parts by mass, more preferably 40 to 80 parts by mass, further preferably 50 to 70 parts by mass, and particularly preferably 55 to 65 parts by mass, relative to 100 parts by mass of the total contents of the component (A) and the component (B). In particular, in respect of maintaining pattern-forming property or transparency of a protective film, the content of the component (A) is preferably 35 parts by mass or more, more preferably 40 parts by mass or more, further preferably 50 parts by mass or more, and particularly preferably 55 parts by mass or more relative to 100 parts by mass of the total amount of the component (A) and the component (B).

As the component (C), conventionally known compounds can be used without particular restrictions. In respect of forming on a substrate a refractive index-adjusting pattern (as thin as 10 μm or less) with a sufficient resolution, it is preferred that an oxim ester compound be contained.

The oxim ester compound is preferably a compound represented by the following formula (1), a compound represented by the following formula (2) or a compound represented by the following formula (3):

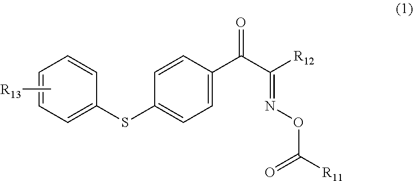

In the formula (1), it is preferred that R₁₁ and R₁₂ be independently an alkyl group having 1 to 12 carbon atoms, a cycloalkyl group having 4 to 10 carbon atoms, a phenyl group or a tolyl group. R₁₁ and R₁₂ are preferably an alkyl group having 1 to 8 carbon atoms, a cycloalkyl group having 4 to 6 carbon atoms, a phenyl group or a tolyl group, more preferably an alkyl group having 1 to 4 carbon atoms, a cycloalkyl group having 4 to 6 carbon atoms, a phenyl group or a tolyl group. R₁₃ is —H, —OH, —COOH, —O(CH₂)OH, —O(CH₂)₂OH, —COO(CH₂)OH or —COO(CH₂)₂OH. R₁₃ is preferably —H, —O(CH₂)OH, —O(CH₂)₂OH, —COO(CH₂)OH or —COO(CH₂)₂OH, more preferably —H, —O(CH₂)₂OH or —COO(CH₂)₂OH.

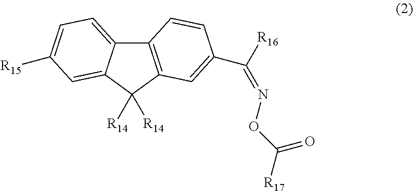

In the formula (2), plural R₁₄s are independently an alkyl group having 1 to 6 carbon atoms, and are preferably a propyl group. The plural R₁₄s may be the same or different R₁₅ is —NO₂ or —ArCO (wherein Ar is a substituted or unsubstituted aryl group). As the Ar, a tolyl group is preferable. As the substituent when R₁₅ has a substituent, an alkyl group having 1 to 6 carbon atoms can be given.

R₁₆ and R₁₇ are independently an alkyl group having 1 to 12 carbon atoms, a phenyl group or a tolyl group. A methyl group, a phenyl group or a tolyl group are preferable.

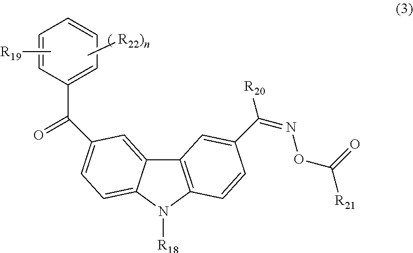

In the formula (3), R₁₆ is an alkyl group having 1 to 6 carbon atoms, with an ethyl group being preferable.

R₁₉ is an organic group having an acetal bond, and is preferably a substituent that corresponds to R₁₉ contained in a compound represented by the formula (3-1) given later.

R₂₀ and R₂₁ are independently an alkyl group having 1 to 12 carbon atoms, a phenyl group or a tolyl group. R₂₀ and R₂₁ are preferably a methyl group, a phenyl group or a tolyl group, with a methyl group being more preferable.

R₂₂ is an alkyl group having 1 to 6 carbon atoms. n is an integer of 0 to 4. When plural R₂₂s are present, the plural R₂₂s may be the same or different.

As the compound represented by the formula (1), a compound represented by the following formula (1-1) and a compound represented by the following formula (1-2) can be given. The compound represented by the following formula (1-1) can be commercially available as IRGACURE OXE-01 (manufactured by BASF Japan, Ltd.).

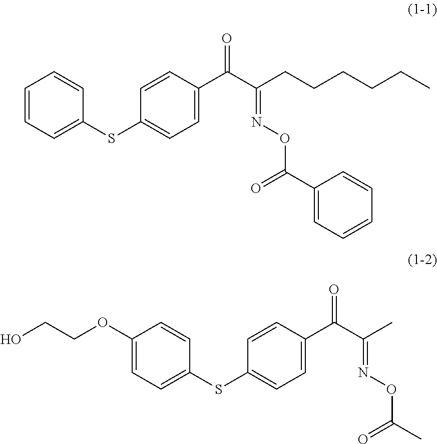 [SMILES: CCCCCC/C(=N\OC(=O)c1ccccc1)C(=O)c1ccc(Sc2ccccc2)cc1 ; CC(=O)O/N=C(\C)C(=O)c1ccc(Sc2ccc(OCCO)cc2)cc1]

As the compound represented by the above formula (2), a compound represented by the following formula (2-1) can be given. The compound represented by the following formula (2-1) can be commercially available as DFI-091 (manufactured by Daito Chemix Co., Ltd.).

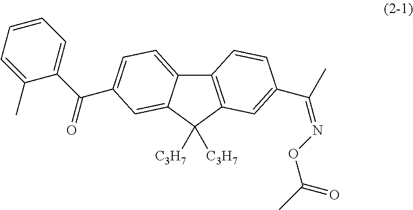

As the compound represented by the above formula (3), a compound represented by the following formula (3-1) can be given. The compound represented by the following formula (3-1) can be commercially available as Adeka Optomer-N-1919 (product name, manufactured by Adeka Corporation).

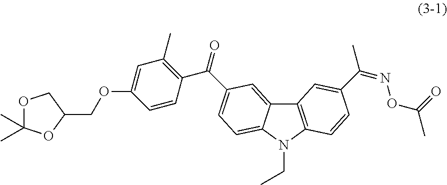 [SMILES: CCn1c2ccc(C(=O)c3ccc(OCC4COC(C)(C)O4)cc3C)cc2c2cc(/C(C)=N\OC(C)=O)ccc21]

As other oxime ester compounds, it is preferable to use a compound represented by the following formula (4) or a compound represented by the following formula (5):

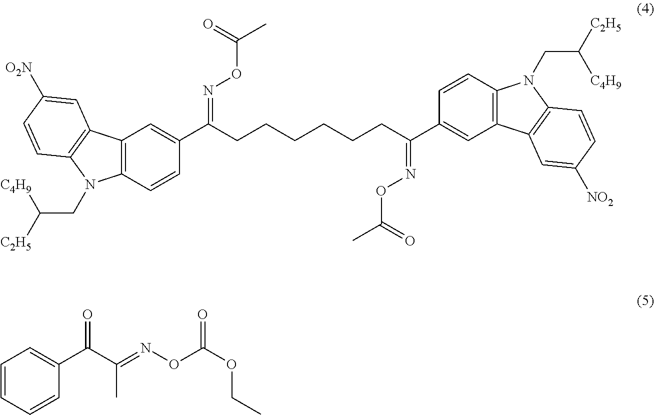

Among these, the compound represented by the above formula (1-1) is significantly preferable. Meanwhile, whether the compound represented by the above formula (1-1) is included in a cured film can be judged by checking whether heptanonitrile and benzoic acid can be detected when the cured film is subjected to pyrolysis gas chromatography mass spectrometry. If the cured film is not subjected to a high-temperature heating step, it can be understood that the compound represented by the above formula (1-1) is contained in the cured film when heptanonitrile and benzoic acid are detected.

As for the detection peak area of benzoic acid by pyrolysis gas chromatography mass spectrometry of a cured film, it can be detected within a range of 1 to 10% relative to the detection peak area of heptanonitrile.

As for the pyrolysis gas chromatography mass spectrometry, it is preferable to conduct gas chromatography mass spectrometry for a gas generated by heating a measurement sample at 140° C. The heating time of the above-mentioned measurement sample may be within a range of 1 to 60 minutes. The heating time is preferably 30 minutes. One example of the measurement conditions of the pyrolysis gas chromatography mass spectrometry is given below.

### (Measurement Conditions of Pyrolysis Gas Chromatography Mass Spectrometry)

Measurement apparatus product name, GC/MS OP-2010 manufactured by Shimadzu Corporation)
Column HP-5MS (product name, manufactured by Agilent Technologies Co., Ltd.) Oven Temp: heated at 40° C. for 5 minutes, and the temperature was elevated to 300° C. at a rate of 15° C./min
Carrier gas: Helium, 1.0 mL/min
Interface temperature: 280° C.
Ion source temperature: 250° C.
Amount of injected sample: 0.1 mL

The content of the component (C) is preferably 0.1 to 10 parts by mass, more preferably 1 to 5 parts by mass, further preferably 1 to 3 parts by mass, and particularly preferably 1 to 2 parts by mass, relative to 100 parts by mass of the total content of the component (A) and the component (B).

In respect of further improving the rust prevention property of the protective film, it is preferred that the composition further comprise a triazole compound having a mercapto group, a tetrazole compound having a mercapto group, a thiadiazole compound having a mercapto group, a triazole compound having an amino group or a tetrazole compound having an amino group (hereinafter often referred to as the component (D)). As the triazole compound having a mercapto group, 3-mercapto-triazole (product name: 3MT manufactured by Wako Pure Chemical Co., Ltd.) can be given. As the thiadiazole compound having a mercapto group, 2-amino-5-mercapto-1,3,4-thiazole (product name: ATT manufactured by Wako Pure Chemical Co., Ltd.) can be given, for example.

As the above-mentioned triazole compound having an amino group, benzotriazole, 1H-benzotriazole-1-acetonitrile, benzotriazole-5-carboxylic acid, 1H-benzotriazole-1-methanol, a compound obtained by substitution of an amino group with carboxybenzotriazole, a compound obtained by substitution of an amino group with a triazole compound having a mercapto group such as 3-mercaptotriazole and 5-mercaptotriazole, or the like can be given.

As the above-mentioned tetrazole compound having an amino group, 5-amino-1H-tetrazole, 1-methyl-5-amino-tetrazole, 1-methyl-5-mercapto-1H-tetrazole, 1-carboxymethyl-5-amino-tetrazole, or the like can be given. These tetrazole compounds may be water-soluble salts thereof. Specific examples thereof include alkali metal salts such as salts of sodium, potassium and lithium of 1-methyl-5-amino-tetrazole.

If the composition contains the component (D), the content thereof is preferably 0.05 to 5.0 parts by mass, more preferably 0.1 to 2.0 parts by mass, further preferably 0.2 to 1.0 parts by mass, and particularly preferably 0.3 to 0.8 parts by mass, relative to 100 parts by mass of the total content of the component (A) and the component (B).

In respect of preventing generation of residues after development, it is preferred that the photosensitive resin composition according to this embodiment contain a phosphoric acid ester containing a photopolymerizable unsaturated bond (hereinafter often referred to as the component (E)). In the specification of the present invention, a phosphoric acid ester compound is not included in the photopolymerizable compound as the component (B).

As the phosphoric acid ester containing a photopolymerizable unsaturated bond as the component (E), in respect of attaining both adhesiveness with an ITO electrode and developability at a high level, while sufficiently ensuring rust prevention property of a protective film to be formed. Phosmer series (Phosmer-M, Phosmer-CL, Phosmer-PE, Phosmer-MH, Phosmer-PP or the like, product name, manufactured by Uni-Chemical Co., Ltd) or KAYAMER series (PM21, PM-2 or the like, product name, manufactured by Nippon Kayaku Co., Ltd) are preferable.

If the component (E) is contained, the content thereof is preferably 0.05 to 5.0 parts by mass relative to 100 parts by mass of the total amount of the component (A) and the component (B), more preferably 0.1 to 2.0 parts by mass, further preferably 0.2 to 1.0 parts by mass, with 0.2 to 0.6 parts by mass being particularly preferable.

### (High Refractive Index Layer)

The high refractive index layer is a layer having a higher refractive index than that of the photosensitive resin layer. Meanwhile, the refractive index at a wavelength of 633 nm is normally 1.40 to 1.49.

In the invention, the high refractive index layer 30 is mainly composed of an organic substance as in the case of the photosensitive resin layer. As a result, developability is improved. It is preferred that the high refractive index layer 30 consist essentially of an organic substance. The “mainly composed of an organic substance”, the “consist essentially of an organic substance”, the “organic substance” and the “essentially do not comprise a metal oxide” are as defined for the above-mentioned photosensitive resin layer.

The high refractive index layer mentioned above have a refractive index at 633 nm of preferably 1.50 to 1.90, more preferably 1.53 to 1.85, further preferably 1.55 to 1.75. By allowing the refractive index at 633 nm of the high refractive index layer to be 1.50 to 1.90, when a laminate shown in FIG. 2 is prepared, the refractive index becomes a value that is intermediate between a refractive index of a transparent electrode pattern 50a of ITO or the like and a refractive index of various members (e.g. OCA for adhering cover glass used for allowing it to be modular and a transparent electrode pattern) used on the photosensitive resin layer 20, whereby it becomes possible to decrease difference in color between a part where transparent electrode patterns (ITO, etc.) are formed and a part where transparent electrode patterns are not formed, and the “pattern visibility phenomenon” can be prevented. In addition, the intensity of reflected light of the entire screen can be decreased, whereby a decrease in transmittance on the screen can be prevented. The refractive index can be measured with reference to the Examples of the specification.

The refractive index of the transparent electrode such as ITO is preferably 1.80 to 2.10, more preferably 1.85 to 2.05, with 1.90 to 2.00 being further preferable. In addition, the refractive index of members such as OCA is preferably 1.45 to 1.55, more preferably 1.47 to 1.53, and further preferably 1.48 to 1.51.

The thickness of the high refractive index layer mentioned above is preferably 50 to 1000 nm, further preferably 50 to 500 nm, more preferably 60 to 300 nm, particularly preferably 70 to 250 nm, with 80 to 200 nm being significantly preferable. By allowing the film thickness to be 50 to 1000 nm, the intensity of reflected light of the entire screen mentioned above can be further decreased.

In respect of refractive index, developability, adaptability to the environment, and general versatility, it is preferred that a high refractive index composition constituting the high refractive index layer contain a compound having a triazine ring, a compound having an isocyanuric acid skeleton, a compound having a fluorene skeleton, a compound having a biphenyl skeleton or a compound having a naphthalene skeleton (hereinafter also referred to as the component (F)). It is more preferred that the high refractive index composition contain a compound having a triazine ring or a compound having an isocyanuric acid skeleton, since excellent developability and uniformity in formation of thin film are exhibited in addition to maintaining high refractive index. As a result, it becomes possible to improve the refractive index at a wavelength at 633 nm.

As the compound having a triazine ring, a polymer having a triazine ring in the structural unit can be given. A compound having a structural unit represented by the following formula (6) or the like can be given.

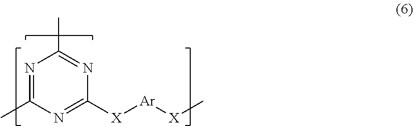

wherein Ar is a divalent group that contains at least one selected from an aromatic ring (the number of carbon atoms is 6 to 20, for example) and a heterocyclic ring (the number of atoms is 5 to 20, for example). Xs are respectively NR¹. R¹s are independently a hydrogen atom, an alkyl group (the number of carbon atoms is 1 to 20, for example), an alkoxy group (the number of carbon atoms is 1 to 20, for example), an aryl group (the number of carbon atoms is 6 to 20, for example) or an aralkyl group (the number of carbon atoms is 7 to 20, for example). Plural Xs may be the same or different.

Specifically, a hyperbranched polymer having a triazine ring is preferable. For example, it can be commercially available as HYPERTECH UR-101 (product name, manufactured by Nissan Chemical Industries, Ltd.).

This hyperbranched polymer is obtained, for example, by adding dropwise a dimethylacetamide solution of 2,4,6-trichloro-1,3,5-triazine to a dimethylacetamide solution of m-phenyldiamine to initiate polymerization and adding dropwise 2-aminopropanol to cause a reaction, followed by precipitation in an aqueous ammonia solution.

It is possible to allow an acid value to be contained by modifying the resulting hyperbranched polymer having a triazine ring with phthalic acid, succinic acid, etc.

The “isocyanuric acid skeleton” of the compound having an isocyanuric acid skeleton means a group obtained by removing three hydrogen atoms from isocyanuric acid. As the compound having an isocyanuric acid skeleton, a compound represented by the following formula (7) is given.

Specifically, triallyl isocyanurate is referable.

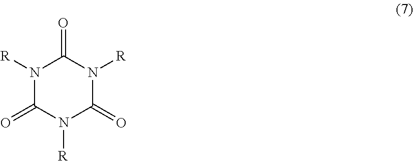

wherein Rs are independently a hydrogen atom, a halogen atom, —R²OH (R² is an alkylene having 1 to 6 carbon atoms) or an aryl group, with an aryl group being preferable.

As the halogen atom, a chlorine atom is preferable.

As —R²OH, a methylol group and a hydroxyethyl group are preferable.

For the high refractive index composition constituting the high refractive index layer, in respect of refractive index, developability, patterning property, and further transparency, it is preferable to use a compound having a triazine ring or a compound having an isocyanuric acid skeleton, and a compound having a fluorene skeleton, a compound having a biphenyl skeleton or a compound having a naphthalene skeleton in combination.

As the compound having a fluorene skeleton, a compound having a 9,9-bis[4-2-(meth)acryloyloxyethoxy]phenyl)fluorene skeleton is preferable. The above compound may be modified with (poly)oxyethylene or (poly)oxypropylene. These are commercially available as, for example, EA-200 (product name, manufactured by Osaka Gas Chemical Co., Ltd.). Further, it may be epoxy-modified with epoxy acrylate. These are commercially available as GA5000 or EG200 (product name, manufactured by Osaka Gas Chemical Co., Ltd.), for example.

As the compound having a biphenyl skeleton, a compound having o-phenylphenol acrylate is preferable. An epoxy acrylate compound having a biphenyl skeleton is more preferable. These are commercially available as A-LEN-10 (product name, manufactured by Shin-Nakamura Chemical Co., Ltd), M-106 (product name, manufactured by Toagosei Co., Ltd.), KAYARAD OPP-1, HRM-3000H (product name, manufactured by Nippon Kayaku Co., Ltd.), for example.

The compound having a naphthalene skeleton is commercially available as KAYARD BNP-1 (product name, manufactured by Nippon Kayaku Co., Ltd.).

As for the content of the component (F) in the high refractive index composition, in order to adjust the refractive index for light with a wavelength of 633 nm of the high refractive index layer to be In a range of 1.5 to 1.9, the following range is preferable.

When a compound having a fluorene skeleton is contained, it is preferred that the compound having a fluorene skeleton be contained in an amount of 10 to 100 parts by mass relative to 100 parts by mass, more preferably 20 to 90 parts by mass, further preferably 30 to 90 parts by mass, and particularly preferably 70 to 90 parts by mass of the total amount of the component (F) in the high refractive index composition.

When a compound having a triazine ring is contained, it is preferred that the compound be contained in an amount of 10 to 100 parts by mass, more preferably 10 to 50 parts by mass, further preferably 10 to 40 parts by mass, and particularly preferably 10 to 30 parts by mass, relative to 100 parts by mass of the component (F).

When a compound having an isocyanuric acid skeleton is contained, the compound is preferably contained in an amount of 10 to 90 parts by mass, more preferably 20 to 80 parts by mass, and further preferably 30 to 70 parts by mass relative to 100 parts by mass of the total amount of the component (F).

When a compound having a biphenyl skeleton or a compound having a naphthalene skeleton is contained, the compound is contained preferably in an amount of 5 to 70 parts by mass, more preferably 5 to 65 parts by mass, and further preferably 5 to 60 parts by mass relative to 100 parts by mass of the total amount of the component (F).

The “photosensitive resin composition” and the “high refractive index composition” mentioned above means a composition in a state that no solvent is contained. The content of each component is an amount ratio relative to the total content of the components other than the solvent.

The high refractive index composition mentioned above may essentially consist of only one of the components (F) mentioned above. That is, the high refractive index layer may essentially consist of the component (F).

Here, the “essentially” means that 95 mass % or more and 100 mass % or less (preferably 98 mass % or more and 100 mass % or less) of the components constituting the composition or the layer is the above-mentioned components.

The high refractive index composition constituting the high refractive index layer may optionally contain one or more of the components (A) to the component (E) as explained with reference to the photosensitive resin layer.

Each of the compositions forming the photosensitive resin layer and the high refractive index layer may contain a known additive, according to need. As the additive, an organosiloxane such as octamethylcyclotetrasiloxane, a polymerization inhibitor such as 2,2′-methylene-bis(4-ethyl-6-tert-butylphenol), etc. can be given.

As mentioned above, in the transfer-type photosensitive refractive-index adjustment film of the invention, the photosensitive resin layer and the high refractive index layer are composed mainly of an organic substance. In particular, it is preferred that the photosensitive resin layer and the high refractive index layer essentially do not comprise a metal oxide. The “essentially do not comprise” means that the content of a metal oxide is 0 to 1 mass % relative to the total mass of the photosensitive resin layer and the high refractive index layer. The content of the metal oxide is preferably from 0 to 0.5 mass %, more preferably from 0 to 0.01 mass %, further preferably from 0 to 0.001 mass %, with 0 mass % being particularly preferable. In order to allow the content of the metal oxide to be 0 mass %, it is required not to use a metal oxide as a raw material of the composition for forming the photosensitive resin layer and the high refractive index layer.

The content of the metal oxide can be measured by an atomic absorption photometer (product name: “Z-5010” manufactured by Hitachi High-Technologies Corporation).

Examples of the metal oxide include zirconium oxide, titanium oxide, tin oxide, zinc oxide, indium tin oxide, indium oxide, aluminum oxide, silicon oxide, glass and the like.

In the transfer-type photosensitive refractive index adjustment film of the invention, the minimum value of the visible ray transmittance at 400 to 700 nm of the photosensitive refractive index-adjusting transfer film is preferably 90.00% or more, more preferably 90.50% or more, and further preferably 90.70% or more. If the transmittance for visible rays with a wavelength of 400 to 700 nm (that is a common visible ray wavelength region) is 90.00% or more, when a transparent electrode in a sensing region of a touch panel (touch sensor) is protected, lowering in image display quality, shade and luminance in a sensing region can be sufficiently suppressed. The maximum value of the visible ray transmittance is normally 100% or less. The visible ray transmittance can be measured with reference to the Examples of the specification.

The photosensitive resin layer 20 and the high refractive index layer 30 of the transfer-type photosensitive refractive index-adjusting film can be formed by preparing a coating liquid containing a photosensitive resin composition and a high refractive index composition, and then applying this liquid respectively to the supporting film 10 and the protective film 40, followed by drying to allow them to be bonded to each other. Alternatively, it can be formed by applying a coating liquid containing a photosensitive resin composition on the supporting film 10, followed by drying. Thereafter, on the photosensitive resin layer 20, a coating liquid containing a high refractive index composition is applied, dried, followed by bonding of the protective film 40.

The coating liquid can be obtained by uniformly dissolving or dispersing in a solvent each component constituting the photosensitive resin composition and the high refractive index composition mentioned above.

No specific restrictions are imposed on a solvent used as a coating liquid, and known solvents can be used. Specific examples thereof include acetone, methyl ethyl ketone, methyl isobutyl ketone, toluene, methanol, ethanol, propanol, butanol, methylene glycol, ethylene glycol, propylene glycol, ethylene glycol monomethyl ether, ethylene glycol monoethyl ether diethylene glycol dimethyl ether, diethylene glycol ethyl methyl ether, diethylene glycol diethyl ether, propylene glycol monomethyl ether, ethylene glycol monobutyl ether acetate, diethylene glycol monoethyl ether acetate, propylene glycol monomethyl ether acetate, chloroform, and methylene chloride.

As the coating method, doctor blade coating method, meyer bar coating method, roll coating method, screen coating method, spinner coating method, ink jet coating method, spray coating method, dip coating method, gravure coating method, curtain coating method, die coating method or the like can be given.

No specific restrictions are imposed on drying conditions. The drying temperature is preferably 60 to 130° C., and the drying time is preferably 0.5 to 30 minutes.

The total thickness of the photosensitive resin layer and the high refractive index layer (hereinafter often referred to as a photosensitive refractive index-adjusting layer) is preferably 30 μm or less, more preferably 20 μm or less, and further preferably 10 μm or less, in respect of followability at the time of laminating. Further, from the viewpoint of suppressing generation of pinholes by protrusions on the substrate, it is preferably 1 μm or more, more preferably 2 μm or more, and further preferably 3 μm or more. When it is 3 μm or more, it is easy to suppress the influence of the protrusions of the substrate as much as possible and to keep the rust prevention property.

The viscosity of the transfer-type photosensitive refractive index-adjusting layer at 30° C. is preferably 15 to 100 mPa·s, more preferably 20 to 90 mPa·s, and further preferably 25 to 80 mPa·s, in respect of preventing a resin composition from oozing out from an end surface of the transfer-type photosensitive refractive index-adjusting film when storing the transfer-type photosensitive refractive index-adjusting film in the shape of a roll and in respect of preventing the photosensitive refractive index-layer from being too hard and breaking into pieces and preventing the broken pieces form adhering to the substrate when the transfer-type photosensitive refractive index-adjusting film is cut.

### (Protective Film)

As the protective film 40, propylene, polypropylene, polyethylene terephthalate, polycarbonate, a polyethylene-vinyl acetate copolymer, a laminate film of a polyethylene-vinyl acetate copolymer and polyethylene or the like can be given.

The thickness of the protective film 40 is preferably 5 to 100 μm. However, in respect of storing after rolling it in the form of a roll, the thickness thereof is preferably 70 μm or less, more preferably 60 μm or less, further preferably 50 μm or less, and particularly preferably 40 μm or less.

Next, an explanation will be made on a method for forming a cured film that satisfies both a function of protecting a transparent electrode by using the transfer-type photosensitive refractive index-adjusting film and a function of allowing an electrode pattern to be invisible or improving visibility of a touch screen.

First, after removing a protective film 40 of a transfer-type photosensitive refractive index-adjusting film 1, the transfer-type photosensitive refractive index-adjusting film is crimped to the surface of the substrate 50 such that the high refractive index layer 30 is in close contact with the substrate 50 (a substrate with a transparent electrode pattern), whereby the high refractive index layer and the photosensitive resin layer are laminated (transferred). As the crimping means, a crimping roll can be given. A crimping roll may be provided with a heating means so as to realize crimping with heating.

As for the heating temperature when crimping with heating is conducted, in respect of adhesiveness of the high refractive index layer 30 and the substrate 50 and also in respect of allowing components constituting the photosensitive resin layer or the high refractive index layer to be hardly cured or decomposed by heating, the heating temperature is preferably 10 to 160° C., more preferably 20 to 150° C., and further preferably 30 to 150° C.

Further, as for the crimping pressure when crimping with heating is conducted, in respect of suppressing deformation of the substrate 50 while fully ensuring adhesiveness of the high refractive index layer 30 and the substrate 50, a linear pressure is preferably 50 to 1×10⁵ N/m, more preferably 2.5×10² to 5×10⁴ N/m, and further preferably 5×10² to 4×10⁴ N/m.

Preheating of the substrate is not necessarily required if the transfer-type photosensitive refractive index-adjusting film is crimped with heating as mentioned above. In respect of further improving adhesiveness between the high refractive index layer 30 and the substrate 50, the substrate 50 may be subjected to preheating. At this time, the treatment temperature is preferably 30 to 150° C.

As the substrate, substrates such as a glass plate, a plastic plate and a ceramic plate used in a touch panel (touch sensor) can be given. On the substrate, an electrode on which a cured film is formed is provided. As the electrode, an electrode such as ITO, Cu, Al and Mo can be given. On the substrate, an insulating layer may be provided between the substrate and the electrode.

Next, a prescribed part of the transferred photosensitive refractive index-adjusting layer is irradiated with active rays through a photomask. When irradiating active rays, if the supporting film 10 on the photosensitive refractive index-adjusting layer is transparent, the photosensitive refractive index-adjusting film is irradiated directly with active rays. If the supporting film 10 is not transparent, irradiation of active rays is conducted after removing the supporting film. As the light source of active rays, known sources of active rays can be used.

The irradiation amount of active rays is 1×10² to 1×10⁴ J/m². At the time of irradiation, heating can be simultaneously conducted. If the irradiation amount of the active rays is 1×10² J/m² or more, photo-curing can be sufficiently proceeded. If the irradiation amount is 1×10⁴ J/m² or less, discoloration of the photosensitive refractive index-adjusting layer tends to be suppressed.

Subsequently, an unexposed part of the photosensitive resin layer and the high refractive index layer after irradiation of active rays is removed by a developer, a refractive index-adjusting pattern that covers part or all of the transparent electrode is formed if the supporting film 10 is laminated on the photosensitive refractive index-adjusting layer after irradiation of active rays, development is conducted after removing it.

Developing can be conducted by known methods such as spraying, showering, immersion swinging, brushing and scrapping. Among these methods, development by spraying by using an aqueous alkaline solution is preferable in respect of environment and safety. The temperature or time of developing can be adjusted within a conventionally known range.

An electronic component according to the present embodiment is provided with a refractive index-adjusting pattern formed by using the transfer-type photosensitive refractive index-adjusting film. As the electronic component, a touch panel, a liquid crystal display, an organic electronic luminescence device, a solar battery module, a print circuit board, electronic paper or the like can be given.

FIG. 3 is a schematic top view showing one example of a capacitive touch panel. The touch panel shown in FIG. 3 has a touch screen 102 for detecting touch position detection coordinates on one side of a transparent substrate 101. A transparent electrode 103 and a transparent electrode 104 are provided on the substrate 101 in order to detect a change in electrostatic capacitance in this region.

A transparent electrode 103 and a transparent electrode 104 respectively detect the X-position coordinate and the Y-position coordinate of the touch position.

On the transparent substrate 101, a lead-out wiring 105 for transmitting detected signals of the touch position from the transparent electrode 103 and the transparent electrode 104 to external circuits is provided. The lead-out wiring 105 and the transparent electrode 103 and the transparent electrode 104 are connected by a connection electrode 106 provided on the transparent electrode 103 and the transparent electrode 104. On an end part opposite to the connection part of the transparent electrode 103 and the transparent electrode 104 of the lead-out wiring 105, a connection terminal 107 for connection with external circuits is provided.

As shown in FIG. 3, by forming a refractive index-adjusting pattern 123, a function as a protective film of the transparent electrode 103, the transparent electrode 104, the lead-out wiring 105, the connection electrode 106 and the connection terminal 107, and a function of adjusting the refractive index of a sensing region (touch screen 102) formed of the transparent electrode pattern are simultaneously attained.

### EXAMPLES

Hereinbelow, the present invention will be explained in more detail with reference to the Examples, which should not construed as limiting the scope of the invention.

### [Preparation of a Binder Polymer Solution (A1)]

In a flask provided with a stirrer, a reflux condenser, an inert gas introduction port and a thermometer, the components (1) shown m Table 1 were charged, and heated to 80° C. in a nitrogen gas atmosphere. While keeping the reaction temperature to 80° C.±2° C., the component (2) shown in Table 1 were added dropwise homogenously for 4 hours. After dropwise addition of the component (2), stirring was conducted at 80° C.±2° C. for 6 hours, whereby a solution (solid matter content: 45 mass %) of a binder polymer having a weight-average molecular weight of 65,000, an acid value of 78 mgKOH/g and a hydroxyl value of 2 mgKOH/g was obtained (A1).

TABLE 1

| | | Blended amount (parts by mass) |
|---|---|---|
| | | (A1) |
| (1) | Propylene glycol | 62 |
| | monomethyl ether | |
| | Toluene | 62 |
| (2) | Methacrylic acid | 12 |
| | Methyl methacrylate | 58 |
| | Ethyl acrylate | 30 |
| | 2,2-azobis | 1.5 |
| | (isobutyronitrile) | |

| | |
|---|---|
| Weight-average molecular weight | 65,000 |
| Hydroxyl value (mgKOH/g) | 2 |
| Acid value (mgKOH/g) | 78 |
| Tg ^{(° C.)} | 60 |

### [Measurement Method of Weight-Average Molecular Weight]

The weight-average molecular weight (Mw) was measured by gel permeation chromatography (GPC) and converted by a calibration line of standard polystyrene. Conditions of GPC are shown below.

### <GPC Conditions>

Pump: L-6000 (product name, manufactured by Hitachi, Ltd.)

Column: Gealpack GL-R420. Gelpack GL-R430, Gelpack GL-R440, product names, all are manufactured by Hitachi Chemical Co., Ltd.)

Eluent: Tetrahydrofuran

Measurement temperature: 40° C.

Flow rate: 2.05 mL/min

Detector L-3300 (product name, RI detector, manufactured by Hitachi, Ltd.)

### [Method for Measuring Acid Value]

The binder polymer solution was heated at 130° C. for 1 hour, and volatile matters were removed to obtain solid matters. Then, 1 g of the solid polymer was preciously weighed. 30 g of acetone was added to this polymer, and the polymer was uniformly dissolved therein. Subsequently, an appropriate amount of phenolphthalein as an indicator was added thereto, and titration was conducted by using a 0.1N KOH aqueous solution. An acid value was calculated by the following formula:

Acid value: 10×Vf×56.1/(Wp×I)

In the formula, Vf shows a titration amount (mL) of an aqueous solution of KOH, Wp is a mass (g) of the resin solution measured, and I is a ratio (mass %) of non-volatile matters in the resin solution measured.

### [Method for Measuring Hydroxyl Value]

The binder polymer solution was heated at 130° C. for 1 hour, and volatile matters were removed to obtain solid matters. 1 g of the solid matters were preciously weighed, and the polymer was put in an Erlenmeyer flask 10 mL of a 10 mass % anhydrous acetic pyridine solution was added, and heated at 100° C. for 1 hour. After the heating, 10 mL of water and 10 mL of pyridine were added, and heated at 100° C. for 10 minutes. Thereafter, by using an automatic titrator (product name: “COM-1700” manufactured by Hiranuma Sangyo Co., Ltd.), neutralization titration was conducted with 0.5 mol/L of an ethanol solution of potassium hydroxide. The hydroxyl value was calculated by the following formula:

Hydroxyl value=(A−B)×f×28.05/sample (g)+acid value

In the formula, A is the amount (mL) of the 0.5 mol/L-ethanol solution of potassium hydroxide used for a blank test, B is the amount (mL) of the 0.5 mol/L-ethanol solution of potassium hydroxide used for titration and f is a factor.

### Examples 1 to 19 and Comparative Examples 1 to 7

### [Preparation of Coating Liquid for Forming Photosensitive Resin Layer]

The compositions shown in the columns of the “photosensitive resin layer” in Tables 2 to 4 were mixed for 15 minutes by using a stirrer, whereby coating liquids for forming a photosensitive resin layer were prepared.

The symbols for the components in Tables 2 to 4 have the following meaning.

### Component (A)

(A1): A propylene glycol monomethyl ether/toluene solution of a copolymer having a monomer blending ratio (methacrylic acid/methyl methacrylate/ethyl acrylate=12/58/30 (mass ratio)), weight-average molecular weight 65,000, acid value 78 mgKOH/g, hydroxyl value 2 mgKOH/g, Tg 60° C.

### Component (B)

T-1420 (T): Ditrimethylol propane tetraacrylate (product name, manufactured by Nippon Kayaku Co., Ltd.)

### Component (C)

IRGACURE OXE 01: 1,2-octanedione, 1-[(4-phenylthio)phenyl, 2-(O-benzoyloxime)](product name, manufactured by BASF Japan Ltd)

### Component (D)

HAT: 5-amino-1H-tetrazole (product name, manufactured by Toyobo Co., Ltd)

### Component (E)

PM-21: Phosphoric acid ester including a photopolymerizable unsaturated bond (product name, manufactured by Nippon Kayaku Co., Ltd.)

Other components

Antage W-500: 2,2′-methylene-bis(4-ethyl-6-tert-butylphenol) (product name, manufactured by Kawaguchi Chemical Industry Co., Ltd.)
SH-30: Octamethylcyclotetrasiloxane (product name, manufactured by Dow Corning Toray Co., Ltd.)
Methyl ethyl ketone (manufactured by Tonen Chemical Corporation)

### [Preparation of Coating Film for Forming High Refractive Index Layer]

The components in the “high refractive index layer” in Tables 2 to 4 were mixed for 15 minutes by means of a stirrer, whereby a coating liquid for forming a high refractive index layer was prepared.

The numerical symbols in Tables 2 to 4 have the following meanings.

### Component (D)

3MT: 3-Mercapto-triazole (product name, manufactured by Wako Pure Chemical Industries)

### Component (E)

Phosmer-M: 2-(methacryloyloxy) ethyl phosphate (product name, manufactured by Unichemical Co., Ltd.)

### Component (F)

HYPERTECH: Polymer having a triazine skeleton (product name, manufactured by Nissan Chemical Industries, Ltd.)
EA-200: Polyoxyethylene-modified 9,9-bis(4-hydroxyphenyl) fluorenediacrylate (product name, manufactured by Osaka Gas Chemicals Co., Ltd.)
EA-F 5503: A mixture of polyoxyethylene-modified 9,9-bis(4-hydroxyphenyl)fluorenediacrylate/benzyl acrylate/9,9-bis(4-hydroxyphenyl)fluorene skeleton compound (product name, manufactured by Osaka Gas Chemicals Co., Ltd.)
EA-HC 931: Polyoxyethylene-modified 9,9-bis (4-hydroxyphenyl) fluorenediacrylate and other mixture (product name, manufactured by Osaka Gas Chemicals Co., Ltd.)
OPP-1: A monomer having a diphenyl skeleton represented by the following formula (product name: “OPP-1” manufactured by Nippon Kayaku Co., Ltd.)

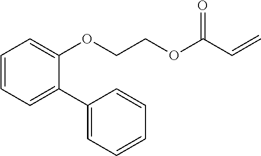 [SMILES: C=CC(=O)OCCOc1ccccc1-c1ccccc1]

BNP-1: A monomer having a naphthalene skeleton represented by the following formula (product name: “BNP-1” manufactured by Nippon Kayaku Co., Ltd.)

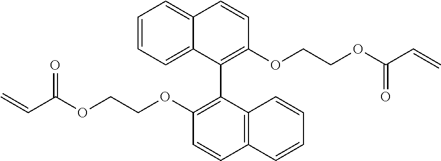 [SMILES: C=CC(=O)OCCOc1ccc2ccccc2c1-c1c(OCCOC(=O)C=C)ccc2ccccc12]

HRM-3000H: An epoxy acrylate compound having a biphenyl skeleton (product name, manufactured by Nippon Kayaku Co., Ltd.)
OZ-S40K-AC: Zirconia dispersion liquid (product name: “Nanouse OZ-S 40 K-AC” manufactured by Nissan Chemical Industries, Ltd.)

Other components

L-7001: Octamethylcyclotetrasiloxane (product name, manufactured by Dow Corning Toray Co., Ltd.)

### [Preparation of Transfer-Type Photosensitive Refractive Index-Adjusting Film]

As the protective film, a 30 μm-thick polyethylene terephthalate film (product name: “E-201F” manufactured by Oji F-Tex Co., Ltd,) was used. The coating liquid prepared above for forming the high refractive index layer was uniformly applied onto a protective film by using a die coater, and dried for 3 minutes in a hot air convection drier of 100° C. to remove the solvent, whereby a high refractive index layer was formed.

As the supporting film, a 16 μm-thick polyethylene terephthalate film (product name: “FB40” manufactured by Toray Industries, Inc.) was used. The coating liquid prepared above for forming the photosensitive resin layer was uniformly applied onto a protective film by using a comma coater, and dried for 3 minutes in a hot air convection drier of 100° C. to remove the solvent, whereby an 8 μm-thick photosensitive resin layer was formed.

The protective film prepared above having the high refractive index layer and the supporting film prepared above having the photosensitive resin layer were laminated such that the high refractive index layer is in close contact with the photosensitive resin layer by means of a laminator (product name: “HLM-3000”, manufactured by Hitachi Chemical Co., Ltd.) at 23° C., whereby a transfer-type photosensitive refractive index-adjusting film was prepared.

For the transfer-type photosensitive refractive index adjustment film or each constituent layer, the following items were evaluated. The results are shown in Tables 2 to 4.

### [Measurement of Refractive Index of High Refractive Index Layer]

A coating liquid for forming the high refractive index layer prepared above was uniformly applied onto a 0.7 mm-thick glass substrate by means of a spin coater, and dried by a hot air convention drier of 100° C. for 3 minutes to remove the solvent, whereby a high refractive index layer was formed.

Subsequently, the obtained high refractive index layer was irradiated with UV rays by means of a parallel ray exposure apparatus (product name: “EXM1201” manufactured by Oak Manufacturing Co., Ltd.) at an exposure amount of 5×10² J/m² (measurement value at 365 nm). Then, the sample was allowed to stand for 30 minutes in a box dryer (model number: “NV50-CA” manufactured by Mitsubishi Electric Corporation) heated to 140° C., thereby to obtain a sample for refractive index measurement having a high refractive index layer. In the Examples and the Comparative Examples in which the component (C) was not contained in the high refractive index layer, the exposure step was omitted.

Subsequently the obtained refractive index measurement sample was measured for the refractive index at 633 nm with ETA-TCM (product name, manufactured by AudioDev GmbH, Co., Ltd.).

The refractive index of the single layer of the refractive index layer in the form of the transfer-type photosensitive refractive index adjustment film is the value of the outermost surface layer of the high refractive index layer on the support film side.

### [Measurement of Film Thickness of High Refractive Index Layer and Photosensitive Resin Layer]

The protective film having the high refractive index layer and the support film having the photosensitive resin layer were measured before being bonded to each other. The film thickness of the high refractive index layer was measured by measuring the high refractive index layer of the protective film having the high refractive index layer prepared above by using F20 (product name, manufactured by FILMETRICS Co., Ltd.). The film thickness of the photosensitive resin layer was measured by measuring the support film having the photosensitive resin layer prepared above by using a digital thickness gauge (product name: “DIGIMICROSTAND MS-5C” manufactured by Nikon Corporation).

### [Measurement of Transmittance (%) and Haze of Cured Film]

While peeling off the protective film of the transfer-type photosensitive refractive index control film prepared above, a laminate was prepared by means of a laminator (product name: “HLM-3000 type” manufactured by Hitachi Chemical Co., Ltd.) on a glass substrate having a thickness of 0.7 mm so that the high refractive index layer was in contact therewith under conditions where a roll temperature of 120° C. a material feed rate of 1 m/min and a pressure bonding pressure (cylinder pressure) of 4×10⁵ Pa (since a substrate having a thickness of 1 mm and a vertical length of 10 cm and a lateral length of 10 cm was used, the linear pressure at this time was 9.8×10³ N/m) to produce a laminate in which a high refractive index layer, a photosensitive resin layer and a supporting film were laminated on a glass substrate.

Subsequently, the obtained laminate was irradiated with UV rays by means of a parallel ray exposure apparatus (product name, “EXM1201”, manufactured by Oak Manufacturing Co., Ltd.) from the upper side of the photosensitive resin layer with an exposure amount of 5×10² J/m² (measured value at a wavelength of 365 nm). Thereafter, the supporting film was removed, and left for 30 minutes at 140° C. in a box-type dryer (model: NV50-CA, manufactured by Mitsubishi Electric Corporation), whereby a sample for measuring the transmittance was obtained.

Subsequently, for the obtained sample for measuring the transmittance, visible ray transmittance and haze value were measured at a measurement wavelength region of 400 to 700 nm by means of a haze meter (product name: “NDH 7000”, manufactured by Nippon Denshoku Industries, Co., Ltd.).

For reference, the measured value of the glass substrate single body is shown in Table 4.

[Test on Residues after Development]

While peeling off the protective film of the resulting transfer-type photosensitive refractive index-adjusting film prepared above, on a PET film provided with an easily-adherable layer (product name: “A4300” manufactured by Toyobo Co., Ltd.), lamination was conducted by using a laminator (product name: “HLM-3000” manufactured by Hitachi Chemical Co., Ltd., a thickness of 125 μm) such that the high refractive index layer was brought into contact therewith under conditions of roll temperature of 120° C., substrate supply speed of 1 m/min and crimping pressure (cylinder pressure) of 4×10⁵ Pa (since a substrate having a thickness of 125 μm and a vertical length of 10 cm and a lateral length of 10 cm was used, the linear pressure at the time of the lamination was 9.8×10³ N/m), whereby a laminate in which the high refractive index layer, the photosensitive resin layer and the supporting film were laminated on the A4300 was obtained.

After preparing the laminate as above, the laminate was stored at a temperature of 23° C. and humidity of 60% for 30 minutes Thereafter, the supporting film laminated on the photosensitive resin layer was removed, and development was conducted by using an aqueous 1.0 mass % sodium carbonate solution at 30° C. for 40 seconds, whereby the high refractive index layer and the photosensitive resin layer were removed. The state of the surface of the resulting substrate was observed by a microscope, and the development residues were evaluated in accordance with the following evaluation criteria:

A: No development residues are generated
B: Slight amount of development residues were generated, but no influences are exerted on the steps afterwards
C: Development residues are generated
D: A large amount of development residues are generated

### [Measurement of Hue (Reflectance R)]

While peeling off the protective film of the obtained transfer-type photosensitive refractive index-adjusting film, on a transparent conductive film (product name: “300R”, manufactured by Toyobo Co., Ltd.), lamination was conducted by using a laminator (product name: “HLM-3000”, manufactured by Hitachi Chemical Co., Ltd.) such that the high refractive index layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate in which the high refractive index layer, the photosensitive resin layer and the supporting film were stacked on the glass substrate was obtained.

Subsequently, the obtained laminate was irradiated with UV rays by means of a parallel ray exposure apparatus (product name: “EXM1201” manufactured by Oak Manufacturing Co., Ltd.) from the upper side of the photosensitive resin layer with an exposure amount of 5×10² J/m² (measured value at a wavelength of 365 nm). Thereafter, the supporting film was removed, whereby a sample for measuring a hue (reflectance R) having a cured film was obtained.

Subsequently, by using a spectral colorimeter (product name: “CM-5” manufactured by Konica Minolta Japan. Inc.), the Y value (this is taken as the reflectance index R) of the obtained sample for measuring hue (reflectance R) was measured, and standardization was conducted by using the following formula:

Standardization of the reflectance R=Actual measured value of the reflectance/Actual measured value of the reflectance of the measurement sample in which only the photosensitive resin layer was laminated (Comparative Example 7)×100

For reference, the measurement values of the transparent conductive film single body are shown in Table 4.

TABLE 2

| Item | | | Ex. 1 | Ex. 2 | Ex. 3 | Ex. 4 | Ex. 5 |
|---|---|---|---|---|---|---|---|
| Photosensitve resin layer | Component (A) | A1 | 60 | 60 | 60 | 60 | 60 |
| | Component (B) | T-1420(T) | 40 | 40 | 40 | 40 | 40 |
| | Component (C) | IRGACURE OXE 01 | 1.7 | 1.7 | 1.7 | 1.7 | 1.7 |
| | Component (D) | HAT | 0.4 | 0.4 | 0.4 | 0.4 | 0.4 |
| | Component (E) | PM-21 | 0.5 | 0.5 | 0.5 | 0.25 | 0.25 |
| | Others | Antage W-500 | 0.1 | 0.1 | 0.1 | 0.1 | 0.1 |
| | | SH-30 | 0.07 | 0.07 | 0.07 | 0.07 | 0.07 |
| | | Methyl ethyl ketone | 50 | 50 | 50 | 50 | 50 |
| High refractive index layer | Component (F) | HYPERTECH | 50 | 50 | 50 | 50 | 50 |
| | | EA-200 | — | — | — | — | — |
| | | EA-F5503 | 50 | 50 | 50 | 50 | 50 |
| | | EA-HC931 | — | — | — | — | — |
| | | OPP-1 | — | — | — | — | — |
| | | BNP-1 | — | — | — | — | — |
| | | OZ-S40K-AC | — | — | — | — | — |
| | Others | Antage W-500 | — | — | — | — | — |
| | | L-7001 | 1 | 1 | 1 | 1 | 1 |

| | | | | | |
|---|---|---|---|---|---|
| Refractive index of high refractive index layer @λ633 nm | 1.615 | 1.615 | 1.615 | 1.615 | 1.615 |
| Film thickness of high refractive index layer (nm) | 90 | 100 | 110 | 125 | 140 |
| Film thickness of photosensitive resin layer (μm) | 8 | 8 | 8 | 8 | 8 |
| Transmittance (%) | 90.72 | 90.82 | 91.01 | 91.07 | 91.29 |
| Haze | 0.47 | 0.38 | 0.65 | 0.75 | 0.6 |
| Standardizatin of refractance R | 89.80% | 89.20% | 86.60% | 85.90% | 83.60% |
| Development residue test | B | B | B | B | B |

| Item | | | Ex. 6 | Ex. 7 | Ex. 8 | Ex. 9 |
|---|---|---|---|---|---|---|
| Photosensitve resin layer | Component (A) | A1 | 60 | 60 | 60 | 60 |
| | Component (B) | T-1420(T) | 40 | 40 | 40 | 40 |
| | Component (C) | IRGACURE OXE 01 | 1.7 | 1.7 | 1.7 | 1.7 |
| | Component (D) | HAT | 0.4 | 0.4 | 0.4 | 0.4 |
| | Component (E) | PM-21 | 0.25 | 0.25 | 0.25 | 0.5 |
| | Others | Antage W-500 | 0.1 | 0.1 | 0.1 | 0.1 |
| | | SH-30 | 0.07 | 0.07 | 0.07 | 0.07 |
| | | Methyl ethyl ketone | 50 | 50 | 50 | 50 |
| High refractive index layer | Component (F) | HYPERTECH | 50 | 50 | 50 | 50 |
| | | EA-200 | — | — | — | — |
| | | EA-F5503 | 50 | 50 | 50 | 50 |
| | | EA-HC931 | — | — | — | — |
| | | OPP-1 | — | — | — | — |
| | | BNP-1 | — | — | — | — |
| | | OZ-S40K-AC | — | — | — | — |
| | Others | Antage W-500 | — | — | — | — |
| | | L-7001 | 1 | 1 | 1 | 1 |

| | | | | |
|---|---|---|---|---|
| Refractive index of high refractive index layer @λ633 nm | 1.615 | 1.615 | 1.615 | 1.615 |
| Film thickness of high refractive index layer (nm) | 175 | 185 | 195 | 205 |
| Film thickness of photosensitive resin layer (μm) | 8 | 8 | 8 | 8 |
| Transmittance (%) | 91.59 | 91.45 | 91.48 | 91.54 |
| Haze | 0.49 | 0.39 | 0.44 | 0.55 |
| Standardizatin of refractance R | 79.70% | 80.50% | 80.80% | 80.60% |
| Development residue test | B | B | B | B |

TABLE 3

| Item | | | Ex. 10 | Ex. 11 | Ex. 12 | Ex. 13 | Ex. 14 |
|---|---|---|---|---|---|---|---|
| Photosensitve resin layer | Component (A) | A1 | 60 | 60 | 60 | 60 | 60 |
| | Component (B) | T-1420(T) | 40 | 40 | 40 | 40 | 40 |
| | Component (C) | IRGACURE OXE 01 | 1.7 | 1.7 | 1.7 | 1.7 | 1.7 |
| | Component (D) | HAT | 0.4 | 0.4 | 0.4 | 0.4 | 0.4 |
| | Component (E) | PM-21 | 0.5 | 0.5 | 0.5 | 0.5 | 0.25 |
| | Others | Antage W-500 | 0.1 | 0.1 | 0.1 | 0.1 | 0.1 |
| | | SH-30 | 0.07 | 0.07 | 0.07 | 0.07 | 0.07 |
| | | Methyl ethyl ketone | 50 | 50 | 50 | 50 | 50 |
| High refractive index layer | Component (F) | HYPERTECH | 50 | 50 | 30 | 20 | 10 |
| | | EA-200 | — | 50 | 70 | 80 | 90 |
| | | EA-F5503 | 50 | — | — | — | — |
| | | EA-HC931 | — | — | — | — | — |
| | | OPP-1 | — | — | — | — | — |
| | | BNP-1 | — | — | — | — | — |
| | | HRM-3000H | — | — | — | — | — |
| | | OZ-S40K-AC | — | — | — | — | — |
| | Others | Antage W-500 | — | — | — | — | — |
| | | L-7001 | 1 | 1 | 1 | 1 | 1 |
| Refractive index of high refractive index layer @λ633 nm | | | 1.615 | 1.615 | 1.612 | 1.605 | 1.609 |
| Film thickness of high refractive index layer (nm) | | | 220 | 203 | 260 | 296 | 285 |
| Film thickness of photosensitive resin layer (μm) | | | 8 | 8 | 8 | 8 | 8 |
| Transmittance (%) | | | 91.26 | 91.3 | 91 | 90.98 | 90.8 |
| Haze | | | 0.6 | 0.35 | 0.4 | 0.41 | 0.39 |
| Standardizatin of refractance R | | | 80.80% | 80.50% | 87.30% | 88.00% | 89.50% |
| Development residue test | | | B | B | A | A | A |
| Item | | | Ex. 15 | Ex. 16 | Ex. 17 | Ex. 18 | Ex. 19 |
| Photosensitve resin layer | Component (A) | A1 | 60 | 60 | 60 | 60 | 60 |
| | Component (B) | T-1420(T) | 40 | 40 | 40 | 40 | 40 |
| | Component (C) | IRGACURE OXE 01 | 1.7 | 1.7 | 1.7 | 1.7 | 1.7 |
| | Component (D) | HAT | 0.4 | 0.4 | 0.4 | 0.4 | 0.4 |
| | Component (E) | PM-21 | 0.25 | 0.25 | 0.25 | 0.25 | 0.25 |
| | Others | Antage W-500 | 0.1 | 0.1 | 0.1 | 0.1 | 0.1 |
| | | SH-30 | 0.07 | 0.07 | 0.07 | 0.07 | 0.07 |
| | | Methyl ethyl ketone | 50 | 50 | 50 | 50 | 50 |
| High refractive index layer | Component (F) | HYPERTECH | 45 | 45 | 40 | 40 | 45 |
| | | EA-200 | 55 | — | 60 | 60 | — |
| | | EA-F5503 | — | — | — | — | — |
| | | EA-HC931 | — | — | — | — | — |
| | | OPP-1 | — | — | — | 8 | — |
| | | BNP-1 | — | 55 | 8 | — | — |
| | | HRM-3000H | — | — | — | — | 55 |
| | | OZ-S40K-AC | — | — | — | — | — |
| | Others | Antage W-500 | — | — | — | — | — |
| | | L-7001 | 1 | 1 | 1 | 1 | 1 |

| | | | | | |
|---|---|---|---|---|---|
| Refractive index of high refractive index layer @λ633 nm | 1.611 | 1.612 | 1.605 | 1.603 | 1.61 |
| Film thickness of high refractive index layer (nm) | 160 | 160 | 193 | 192 | 100 |
| Film thickness of photosensitive resin layer (μm) | 8 | 8 | 8 | 8 | 8 |
| Transmittance (%) | 91.5 | 91.51 | 90.95 | 90.5 | 91.51 |
| Haze | 0.36 | 0.37 | 0.35 | 0.32 | 0.3 |
| Standardizatin of refractance R | 80.10% | 80.00% | 82.00% | 80.00% | 80.00% |
| Development residue test | B | B | B | B | A |

TABLE 4

| Item | | | Comp. Ex. 1 | Comp. Ex. 2 | Comp. Ex. 3 | Comp. Ex. 4 |
|---|---|---|---|---|---|---|
| Photosensitve resin layer | Component (A) | A1 | 60 | 60 | 60 | 60 |
| | Component (B) | T-1420(T) | 40 | 40 | 40 | 40 |
| | Component (C) | IRGACURE OXE 01 | 1.7 | 1.7 | 1.7 | 1.7 |
| | Component (D) | HAT | 0.4 | 0.4 | 0.4 | 0.4 |
| | Component (E) | PM-21 | 0.5 | 0.5 | 0.5 | 0.5 |
| | Others | Antage W-500 | 0.1 | 0.1 | 0.1 | 0.1 |
| | | SH-30 | 0.07 | 0.07 | 0.07 | 0.07 |
| | | Methyl ethyl ketone | 50 | 50 | 50 | 50 |
| High refractive index layer | Component (A) | A1 | — | — | — | — |
| | Component (B) | T-1420(T) | — | — | — | — |
| | Component (C) | IRGACURE OXE 01 | — | — | — | — |
| | Component (D) | HAT | — | — | — | — |
| | | 3MT | — | — | — | — |
| | Component (E) | PM-21 | — | — | — | — |
| | | Phosmer_M | — | — | — | — |
| | Component (F) | HYPERTECH | — | — | — | — |
| | | EA-200 | 35 | 60 | — | — |
| | | EA-F5503 | — | — | — | — |
| | | EA-HC931 | — | — | 35 | 50 |
| | | OPP-1 | — | — | — | — |
| | | BNP-1 | — | — | — | — |
| | | OZ-S40K-AC | 65 | 40 | 65 | 50 |
| | Others | Antage W-500 | — | — | — | — |
| | | L-7001 | — | — | — | — |

| Refractive index of high refractive index layer @λ633 nm | | 1.646 | 1.615 | 1.632 | 1.63 |
|---|---|---|---|---|---|
| Film thickness of high refractive index layer (nm) | | 220 | 220 | 220 | 220 |
| Film thickness of photosensitive resin layer (μm) | | 8 | 8 | 8 | 8 |
| Transmittance (%) | | 91.35 | 91.1 | 91.3 | 91.16 |
| Haze | | 0.33 | 0.37 | 0.37 | 0.38 |
| Standardizatin of refractance R | | 81.60% | 84.40% | 81.70% | 84.00% |
| Development residue test | | D | C | D | D |
| | Item | Comp. Ex. 5 | Comp. Ex. 6 | Comp. Ex. 7 | Reference |

| | | | | | | |
|---|---|---|---|---|---|---|
| Photosensitve resin layer | Component (A) | A1 | 60 | 60 | 60 | Substrate |
| | Component (B) | T-1420(T) | 40 | 40 | 40 | single |
| | Component (C) | IRGACURE OXE 01 | 1.7 | 1.7 | 1.7 | body |
| | Component (D) | HAT | 0.4 | 0.4 | 0.4 | |
| | Component (E) | PM-21 | 0.5 | 0.5 | 0.25 | |
| | Others | Antage W-500 | 0.1 | 0.1 | 0.1 | |
| | | SH-30 | 0.07 | 0.07 | 0.07 | |
| | | Methyl ethyl ketone | 50 | 50 | 50 | |
| High refractive index layer | Component (A) | A1 | 30 | 10 | — | |
| | Component (B) | T-1420(T) | — | — | — | |
| | Component (C) | IRGACURE OXE 01 | 1.7 | 1.7 | — | |
| | Component (D) | HAT | — | 0.4 | — | |
| | | 3MT | 1 | — | — | |
| | Component (E) | PM-21 | 0.25 | — | — | |
| | | Phosmer_M | — | 2 | — | |
| | Component (F) | HYPERTECH | — | — | — | |
| | | EA-200 | 50 | 50 | — | |
| | | EA-F5503 | — | — | — | |
| | | EA-HC931 | 20 | 40 | — | |
| | | OPP-1 | — | — | — | |
| | | BNP-1 | — | — | — | |
| | | OZ-S40K-AC | 102.5 | 193.64 | — | |
| | Others | Antage W-500 | 0.1 | 0.1 | — | |
| | | L-7001 | 0.07 | 0.07 | — | |

| | | | | |
|---|---|---|---|---|
| Refractive index of high refractive index layer @λ633 nm | 1.621 | 1.651 | 1.474 | — |
| Film thickness of high refractive index layer (nm) | 220 | 220 | 0 | — |
| Film thickness of photosensitive resin layer (μm) | 8 | 8 | 8 | — |
| Transmittance (%) | 90.71 | 90.75 | 89.85 | 82.6 |
| Haze | 0.8 | 0.82 | 1.03 | 1.56 |
| Standardizatin of refractance R | 82.10% | 84.80% | 100.00% | 176.50% |
| Development residue test | D | D | A | — |

The compositions of the components shown in Tables 2 to 4 are parts by mass.

As shown in Tables 2 to 4, in the Examples, the standardization value of R (reflectance) became 90% or less, i.e. the reflectance was sufficiently reduced. In the Examples, no development residues were generated, therefore, sufficient developability was exhibited. Further. Comparative Example 7 shows a result where only the photosensitive resin layer was provided.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

### DESCRIPTION OF NUMERICAL SYMBOLS

1. Transfer-type photosensitive refractive index adjustment film
10. Supporting film
20. Photosensitive resin layer
30. High refractive index layer
40. Protective film
50. Substrate with transparent conductive electrode
50a. Transparent electrode pattern
100. Laminate
101. Transparent substrate
102. Touch screen
103. Transparent electrode (X-position coordinate)
104. Transparent electrode (Y-position coordinate)
105. Lead-out wiring
106. Connection electrode
107. Connection terminal
123. Refractive index adjustment pattern

1. A transfer-type photosensitive refractive index adjustment film comprising a supporting film, a photosensitive resin layer provided on the supporting film and a high refractive index layer provided on the photosensitive resin layer,
wherein the photosensitive resin layer and the high refractive index layer are composed mainly of an organic substance.

2. The transfer-type photosensitive refractive index adjustment film according to claim 1, wherein the photosensitive resin layer and the high refractive index layer consist essentially of an organic substance.

3. The transfer-type photosensitive refractive index adjustment film according to claim 1, wherein the photosensitive resin layer and the high refractive index layer essentially do not comprise a metal oxide.

4. The transfer-type photosensitive refractive index adjustment film according to claim 1, wherein the high refractive index layer comprises a compound having a triazine ring or a compound having an isocyanuric acid skeleton.

5. The transfer-type photosensitive refractive index adjustment film according to claim 1, wherein the high refractive index layer comprises a compound having a fluorene skeleton.

6. The transfer-type photosensitive refractive index adjustment film according to claim 1, wherein the high refractive index layer comprises a compound having a biphenyl skeleton.

7. The transfer-type photosensitive refractive index adjustment film according to claim 1, wherein the high refractive index layer comprises a compound having a naphthalene skeleton.

8. The transfer-type photosensitive refractive index adjustment film according to claim 1, wherein the high refractive index layer has a refractive index of 1.50 to 1.90 at a wavelength of 633 nm.

9. The transfer-type photosensitive refractive index adjustment film according to claim 1, wherein the high refractive index layer has a film thickness of 50 to 1000 nm.

10. The transfer-type photosensitive refractive index adjustment film according to claim 1, wherein the photosensitive resin layer comprises a binder polymer, a photopolymerizable compound and a photopolymerization initiator.

11. The transfer-type photosensitive refractive index adjustment film according to claim 10, wherein the photopolymerization initiator comprises an oxime ester compound.

12. The transfer-type photosensitive refractive index adjustment film according to claim 10 wherein the binder polymer has a carboxyl group.

13. The transfer-type photosensitive refractive index adjustment film according to claim 10, wherein the binder polymer has a structural unit derived from at least one compound selected from the group consisting of (meth)acrylic acid, (meth)acrylic acid glycidyl ester, (meth)acrylic acid benzyl ester, styrene, (meth)acrylic acid methyl ester, (meth)acrylic acid ethyl ester, (meth)acrylic acid butyl ester and (meta)acrylic acid 2-ethylhexyl ester.

14. The transfer-type photosensitive refractive index adjustment film according to claim 10, wherein the photosensitive resin layer comprises a phosphoric acid ester compound.

15. The transfer-type photosensitive refractive index adjustment film according to claim 1, wherein the minimum value of the visible ray transmittance of the photosensitive resin layer and the high refractive index layer at a wavelength of 400 to 700 nm is 90.00% or more.

16. The transfer-type photosensitive refractive index adjustment film according to claim 1, wherein the total thickness of the photosensitive resin layer and the high refractive index layer is 30 μm or less.

17. A method for forming a refractive index adjustment pattern that comprises:
a step of laminating the high refractive index layer and the photosensitive resin layer by using the transfer-type photosensitive refractive index adjustment film according to claim 1 such that the high refractive index layer is in close contact with a substrate; and
a step of forming a refractive index adjustment pattern in which, after exposing prescribed parts of the high refractive index layer and the photosensitive resin layer on the substrate, parts other than said prescribed parts are removed, thereby to form a refractive index adjustment pattern.

18. An electronic component comprising a refractive index adjustment pattern obtained by the forming method according to claim 17.
